(19) United States
(12) Patent Application Publication
(10) Pub. No.: US 2012/0168131 A1
(43) Pub. Date: Jul. 5, 2012

(54) HEAT EXCHANGE DEVICE WITH IMPROVED EFFICIENCY

(75) Inventors: Jerome Gavillet, Saint Egreve (FR); Hai Trieu Phan, Grenoble (FR)

(73) Assignee: Commissariat a l'energie atomique et aux energies alternatives, Paris (FR)

(21) Appl. No.: 13/395,770

(22) PCT Filed: Sep. 13, 2010
(86) PCT No.: PCT/EP2010/063337

§ 371 Date: Mar. 13, 2012

(30) Foreign Application Priority Data
Sep. 14, 2009 (FR) 09 56308

(51) Int. Cl. F28D 15/00; B05D 3/06; H05K 13/00; B05D 5/12

(52) U.S. Cl. 165/104.23; 427/58; 427/554; 216/13

(57) ABSTRACT

A method for heat exchange by boiling a polar liquid on a surface including at least one low-wetting zone, including: a) generating appearance of nuclei of vapor bubbles on the low-wetting zone, and causing the nuclei to grow; and b) making the surface wetting by at least one electro-wetting system, to favor detachment of the gas bubbles formed in this manner.

### TECHNICAL FIELD AND PRIOR ART

The present invention relates to a heat exchange device with improved efficiency, which can be used for cooling electronic components.

The boiling phenomenon is very often used in heat exchange devices; this phenomenon may follow one or other of the following two conditions:

pool boiling: in this regime the surface, from which the heat must be dissipated, is immersed in a stagnant, unconfined liquid; the dominant phenomenon of pool boiling is nucleate boiling.

convective and confined boiling: under these conditions the liquid flows into a pipe of hydraulic diameter less than the capillary length of said liquid.

In the case of pool boiling, above a heat flow termed “critical”, the appearance of a continuous layer of vapour is observed, which prevents all contact between the liquid and the wall.

Heat transfers are then substantially reduced.

The temperature of the wall then increases continually, since almost no heat is dissipated subsequently.

A hot point is thus created, which may cause the destruction of the vessel and of the element to be cooled.

In the case of convective boiling confined in a channel the bubbles are generally formed in zones close to the entrance of the channel.

Subsequently, through a confinement effect, they are crushed and coalesce to form vapour locks.

The heat is then principally transmitted through a micro-layer of liquid which is in contact with the wall of the channel.

When heat transfer occurs in confined spaces a premature drying of the walls of the channel is generally observed.

This drying causes a substantial reduction of the heat exchange coefficient, and therefore reduced efficiency of the element to be cooled.

In addition, it has been shown that the wetter the surfaces, the more the critical heat flow increases.

However, the more the wettability of a surface increases, the greater the energy required to form the first nuclei of vapour bubbles.

Vapour bubble formation frequency is then reduced.

One aim of the present invention is consequently to provide a heat exchange surface which has at the same time the advantages of a wetting surface and also sufficient frequency of generation of vapour bubbles.

### DESCRIPTION OF THE INVENTION

The above-stated aim is attained by a low-wetting heat exchange surface incorporating electrical means able to modify the wettability properties of said surface, and to make it hydrophilic on demand.

In order to modify the surface's wettability properties the principle of electro-wetting is used by imposing on the surface after formation of the vapour bubbles a potential increasing the surface's wettability in the area of formation of the vapour bubbles, facilitating detachment of the vapour bubbles.

Initially there is a low-wetting surface, favouring the generation of nuclei of vapour bubbles, and subsequently a wetting surface, favouring the detachment of the gas bubbles.

In other words an active surface is used, the wettability of which can be modified on command, which, over time, advantageously enables the advantages of low wettability and those of satisfactory wettability to be combined.

Through the use of electro-wetting it is possible to modify the surface's wettability properties locally, and thus to generate bubbles in discrete and localised fashion.

This localisation allows the prevention of a flood of bubbles in a zone and their coalescence, which may create a vapour film.

According to the invention, the surface energy of the walls in contact with the liquid is modified by electrical actuation, which enables the heat transfer coefficient to be improved and the appearance of the undesirable heat phenomena to be delayed, i.e. the appearance of the critical heat flow during pool boiling, and drying during convective boiling.

In a particularly advantageous manner the frequency of activation of the electro-wetting means is in phase with the dynamics of formation of the nuclei of vapour bubbles and their detachment from the wall. Bubble generation is then optimal, the effect of which is to improve heat transfer, and therefore cooling of the hot element.

In an embodiment applicable to pool boiling conditions, the zones with variable wettability and their change of wettability are organised in a given manner, in order to distribute bubble generation and their detachment in a manner which is synchronised over time and uniform in space, and to prevent any coalescence of the vapour bubbles.

The risks of appearance of a critical heat flow are then small.

Several electro-wetting systems are preferentially available, distributed under the surface, all of which are controlled simultaneously, so as to cause simultaneously the change of wettability of the surface covering them. The device is then simplified.

In another embodiment suitable for convective boiling conditions, for which the fluid flows into a channel, the zone of variable wettability by electro-wetting coupled to a heat source is located at the entrance to the channel, in order to generate nuclei of vapour bubbles which will grow in size in the form of bubbles in the channel under the effect of the heat provided by the element to be cooled. The times at which bubbles appear are therefore controlled by creating a generator outside the zone in which the nuclei of bubbles habitually appear spontaneously.

These nuclei can be generated in a manner which is sufficiently spaced over time to prevent coalescence of the vapour bubbles and the appearance of vapour locks.

Its thermal transfer is then improved, and drying of the walls is delayed.

The subject-matter of the present invention is then mainly a method to accomplish heat exchanges by boiling a polar liquid on a surface having at least one low-wetting zone, consisting in:

a) generating the appearance of nuclei of vapour bubbles on said low-wetting zone, and causing said nuclei to grow,

b) making said surface wetting by at least one electro-wetting system, in order to favour the detachment of said gas bubbles formed in this manner.

The surface can also be entirely low-wetting, and multiple electro-wetting systems are distributed under this surface; in step b) the electro-wetting systems are all activated simultaneously to favour detachment of said gas bubbles formed.

The surface can comprise a number m of electro-wetting systems, distributed under the surface and able to be activated separately, where m is equal to n+p, where m, n and p are natural integers, where steps a) and b) are applied periodically to the n and to the p electro-wetting systems, where step a) is applied to n systems and step b) to p systems simultaneously, and where step a) is applied simultaneously to the p systems and step b) to the n systems simultaneously.

The period of activation of the electrodes can advantageously be roughly equal to the sum of the period of generation of the nuclei of vapour bubbles and of the growth period of the vapour bubbles, for example between 10 Hz and 100 Hz.

In another example the surface can comprise an electrode in the form of a track running under the surface, where said surface has, above the electrode, alternating low-wetting and wetting zones, and where steps a) and b) apply to the single electrode.

Boiling can be convective and confined, and the surface then forms a portion of a duct in which the polar liquid flows, where said surface is located upstream from the zone where the heat exchange takes place; the surface comprises heating means; during step a), the polar liquid undergoes a heat transfer on the surface.

The subject-matter of the present invention is also a heat exchange device comprising a surface in contact with a polar liquid and intended to extract heat from an element, where said surface comprises at least one system able to modify locally the wettability of the surface in contact with the polar liquid by electro-wetting, where said system comprises at least one electrode associated with a counter electrode and control means to activate an electrode by application of a potential to said electrode, where the wall of the surface has, at least partially, if no potential is applied to said electrode, low wettability properties, and where the system is insulated from the liquid by a dielectric layer.

For example, the polar liquid flows, where said electro-wetting system is located in a portion of the wall upstream from the portion in contact with the element to be cooled, and where said device also comprises means to cause the liquid to flow in the duct, and heating means located in the area of the electro-wetting system.

The electro-wetting system can comprise at least one electrode associated with a counter electrode distributed transversely relative to the liquid's direction of flow.

The at least one electrode has, for example, a ring shape, and the counter electrode is located in the centre of said ring. The external diameter of the electrode is, for example, between 0.1 mm and 1 mm, and the diameter of the counter electrode is between 1 μm and 10 μm, where the distance between the electrode and the counter electrode is, for example, between 1 μm and 50 μm.

The distance between two adjacent electrodes can be between 0.1 mm and 1 mm.

The heating means can be formed by a ring-shaped electrical resistor surrounded by the electrode and surrounding the counter electrode.

In another example embodiment, the electro-wetting system comprises a comb-shaped electrode comprising a body and fingers transverse to the body, where said fingers are aligned roughly in the polar liquid's direction of flow, and a comb-shaped counter electrode, where the fingers of the counter electrode are interdigitated with those of the electrode, where the surface also comprises wetting zones alternating with low-wetting zones along the fingers, and where the heating means pass between the fingers of the electrode and those of the counter electrode.

The wetting zones and the low-wetting zones take, for example, the form of strips roughly perpendicular to the polar liquid's direction of flow, and extend throughout the length of the comb.

In another embodiment the boiling may take place in a vessel, where said surface forms the base of said device, where the electro-wetting system comprises multiple electrodes associated with at least one counter electrode, and where said electrodes are distributed over the entire surface of the wall.

In a particularly advantageous example embodiment the control means activate and deactivate simultaneously all the electrodes periodically.

In another example embodiment, the control means activate and deactivate the electrodes in groups or separately, and periodically, in a phase-shifted manner.

For example, the electrodes are distributed in the form of a draughtsboard.

The entire surface may be wetting, or the zones above the electrodes are low-wetting, and the zones between the zones above the electrodes are wetting. For example, the wetting zones take the form of a grid.

In a variant embodiment of a device with pool boiling the surface can form the base of said device, where the electro-wetting system comprises an electrode in the form of a track running under the surface of the wall, and a track-shaped counter electrode passing beside the electrode.

The surfaces above the tracks are, for example, divided into zones of low wettability by zones of satisfactory wettability.

The electrode and the counter electrode may be configured in the form of a spiral.

The surface above the electrodes comprises, for example, first strips having properties of satisfactory wettability, and second strips having properties of low wettability, where said first and second strips alternate and intersect the various portions of the electrode (108).

In a variant embodiment the electrode and the counter electrode take the form of interdigitated combs, where the surface has wetting zones and low-wetting zones above the electrode. For example, the wetting zones and the low-wetting zones are formed by wetting and low-wetting strips intersecting the fingers of the combs.

For example, the polar liquid is water or an ethylene glycol.

The subject-matter of the present invention is a alos method for the production of a heat exchange device according to the present invention comprising the following steps:

a) deposition of a first electrical insulating layer on a substrate,

b) deposition of an electrical conducting layer on said electrical insulating layer to form electrodes,

c) deposition of a second electrical insulating layer on the electrical conducting layer,

d) deposition on the second electrical insulating layer of a film having low wettability properties.

The method of production of a heat exchange device may comprise the subsequent step e) of production in the film of zones having satisfactory wettability properties. Step e) is obtained, for example, by oxidisation of the film having properties of low wettability (308) by means of a laser.

The method may also comprise the step of etching of the electrical conducting layer.

The substrate is, for example, made from steel, the first electrical insulating layer is made from SiC/SiO₂, and the layer of low wettability is made, for example, from SiOC.

### BRIEF DESCRIPTION OF THE DRAWINGS

The present invention will be better understood using the description which follows and the illustrations, in which:

FIG. 1A is a schematic top view of an example embodiment of a heat exchange surface according to a first embodiment of the present invention,

FIG. 1B is a schematic top view of a variant of the heat exchange surface of FIG. 1A,

FIG. 2 is a top view of a variant embodiment of a heat exchange surface according to a first embodiment of the present invention,

FIG. 3 is a top view of another variant embodiment of a heat exchange surface according to a first embodiment of the present invention,

FIG. 4A is a schematic side view representation of a heat exchange surface according to another embodiment,

FIG. 4B is a top view of a detail of FIG. 4A,

FIG. 4C is a top view of a variant embodiment of the detail of FIG. 4A,

FIG. 5 is a top view of another example embodiment of the other embodiment,

FIGS. 6A to 6D are schematic representations of the different steps of an example of a method of production of a device according to the present invention,

FIGS. 7A and 7B are explanatory diagrams of a wetting surface and a low-wetting surface,

FIGS. 8A and 8B are graphical representations of the change of wettability of two surfaces according to the applied voltage.

### DETAILED ACCOUNT OF PARTICULAR EMBODIMENTS

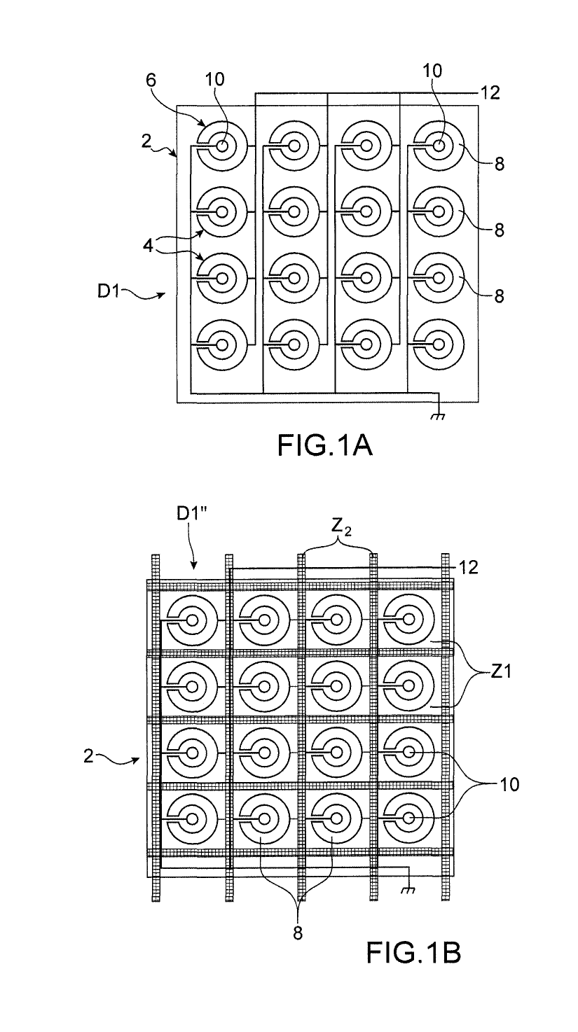

In FIG. 1A a first example of a heat exchange device D1 according to the present invention suitable for pool boiling conditions can be seen. Device D1 comprises a heat exchange surface intended to be covered by a polar liquid (not represented).

The heat exchange surface is intended to be in contact with an element to be cooled (not visible) by its face opposite the face in contact with the polar liquid.

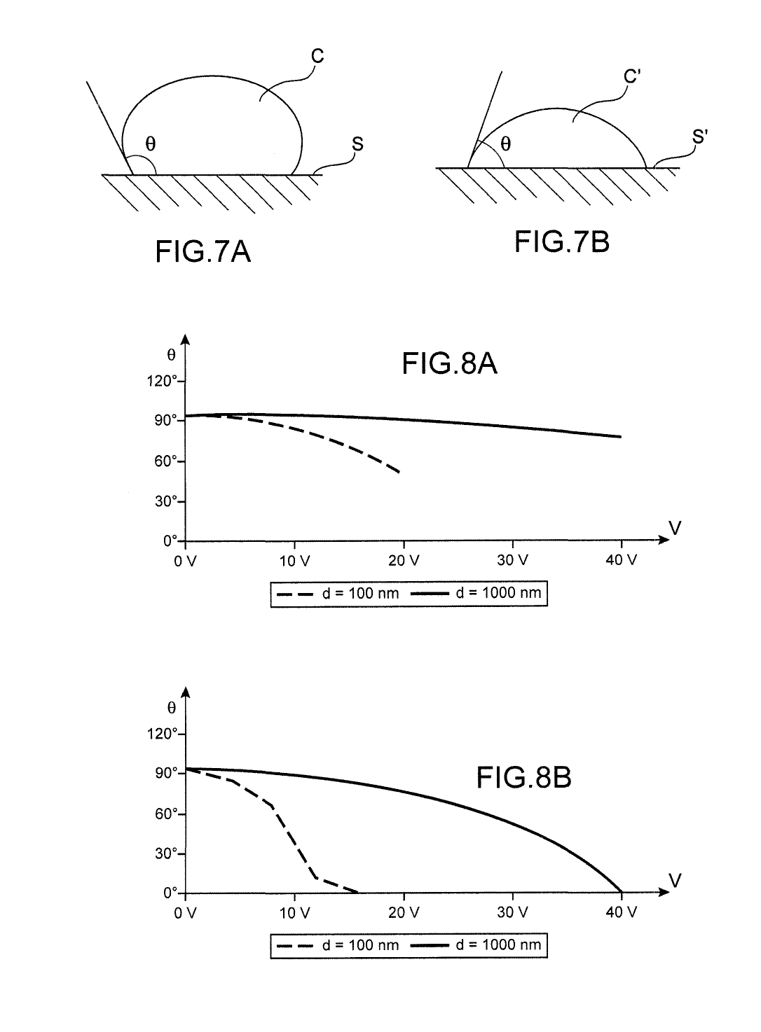

Heat exchange surface 2 has, at least in localised zones 4, properties of low wettability with regard to the polar fluid. One surface has properties of low wettability with regard to a liquid, when contact angle θ is greater than 90° , as represented in FIG. 7A. One surface has properties of satisfactory wettability with regard to a liquid, when contact angle θ is less than 90° , as represented in FIG. 7B.

In the case of water, the term hydrophobic surface is used for a low-wetting surface, and the term hydrophilic for a wetting surface.

In addition, according to the invention, the device has an electro-wetting system 6 in order to modify chronologically the contact angle between the liquid and the heat exchange surface.

Modification of the electrical voltage modifies the wettability properties of surface 2 with regard to the polar fluid.

In the present example the system is able to transform a hydrophobic surface temporarily into a hydrophilic surface.

In the represented example the electro-wetting system comprises multiple electrodes 8 distributed in the plane of the heat exchange surface.

In the represented example the distribution is in the form of lines and columns, but this arrangement is in no sense restrictive.

Each electrode 8 is associated with a counter electrode 10.

In the represented example electrodes 8 have an annular shape connected to a voltage source 12 and a counter electrode 10 is positioned in the centre of each of electrodes 8; in the represented example the counter electrodes 10 are connected to earth.

Electrodes 8 and counter electrodes 10 are covered with a dielectric layer (not represented), separating the fluid of electrodes 8 and counter electrodes 10.

In addition, the heat exchange surface has at least several hydrophobic zones with regard to the polar liquid.

In this example embodiment the entire surface has this property.

In addition the system comprises control means (not represented) to apply a voltage between each electrode 8 and associated counter electrode 10. Only the electrical power is represented.

The control means can therefore apply a voltage to the electrode/counter electrode pairs.

Wetting of a liquid varies according to a law described by the Lippman-Young's equation:

$$cos θ = cos {θ}_{γ} + \frac{{ɛɛ}_{0}}{2 γ d} {V}^{2}$$

where θ is the contact angle at potential V, θ_{y} is the contact angle at potential 0 V, Y is the liquid's surface energy, ε₀ is the permittivity of empty space, ε is the dielectric constant of the insulating layer and d is the thickness of this insulating layer.

Thus, when a potential V is applied the value of cosθ increases.

Angle θ is therefore less than angle θ_{y}. With a sufficient value V, θ becomes less than 90° , making the surface hydrophilic.

Electro-wetting enables the fluid's contact angle to be modified locally.

In the case of water the contact angle can vary between 60° and 110°.

In FIG. 8B, the changes of the wettability of the ethylene glycol can be seen on an insulating layer of dielectric constant equal to 8 covered with a hydrophobic film the contact angle of which is equal to 95°.

The change of contact angle θ according to the voltage applied to the electrode is represented for an insulating layer thickness of 100 nm and an insulating layer thickness of 1000 nm.

It can be seen that, compared to an insulating layer of dielectric constant equal to 2 (represented in FIG. 8A), contact angle θ is reduced more rapidly, and is zero for an insulating layer of 100 nm when the voltage is higher than 15 V, for an insulating layer of thickness 1000 nm when the voltage is equal to or greater than 40 V.

For the sake of simplicity we shall consider the case of water as the polar fluid.

However, it is well understood that any other polar liquid, as a diphasic boiling fluid, may be used, such as for example ethylene glycol mentioned above.

In the remainder of the description the term activation will be used for application of a potential to an electrode.

According to a first particularly advantageous example embodiment of the present invention, activation of the electrodes is accomplished collectively such that all the electrodes of the non-wetting zone are activated simultaneously.

By controlling the frequency of activation of the electrodes, and by choosing a suitable distance between electrodes, the size of the nuclei of bubbles and therefore of the vapour bubbles, is controlled, preventing by this means any risk of coalescence.

The period of nucleation and of growth, during which the electrodes are not activated, is relatively longer than the period of release of the bubbles, during which the electrodes are activated. This example embodiment enables the creation of a large number of bubbles over the entire heat exchange surface to follow, making the heat dissipation more efficient.

The electrodes are positioned relative to one another in a sufficiently spaced manner in order to prevent the bubbles coming into contact with one another and coalescing to form a vapour layer, while the vapour bubbles are growing.

According to a second example embodiment the adjacent electrodes are activated in staggered fashion over time.

This staggered activation over time enables vapour bubbles which are too close to one another to be prevented from coalescing and forming a vapour layer, and enables the use of the effective area generating vapour bubbles to be optimised.

In addition, also in a very advantageous manner, the period of activation of the electrodes is roughly equal to the sum of the period of generation of the nuclei of vapour bubbles and of the period of growth of the vapour bubbles.

The corresponding frequency is between 10 Hz and 100 Hz.

The time between activation of two adjacent electrodes is therefore equal to the time required for nucleation and growth of a vapour bubble. Thus, the efficiency of production of vapour bubbles and therefore of heat dissipation is optimised.

The heat exchange surface can be either fully hydrophobic in its natural state, i.e. without application of any voltage to electrodes 8, or be hydrophobic only above electrodes 8.

According to the first example embodiment all the electrodes are collectively connected to a voltage source.

The system is then simplified in terms of the production of the device and in terms of control.

According to the second example embodiment electrodes 8 can be controlled individually; in this case each electrode 8 is connected to a voltage source individually.

Preferably c, the electrodes are divided into two groups in the form of a draughtsboard, according to their location, the two groups being interwoven, and each electrode in a group is surrounded only by electrodes of the other group.

The two groups are then activated alternatively, advantageously at the frequency mentioned above.

We shall now explain an example of operation of the device in FIG. 1 in cooling the element to be cooled according to the first example embodiment.

None of the electrodes is activated; the surface located above the electrodes is therefore hydrophobic, the consequence of which is to facilitate the appearance of nuclei of vapour bubbles.

The nuclei grow under the effect of the heat provided by the element.

The heat exchange surface is therefore where multiple vapour nuclei of bubbles appear, distributed discretely over the entire surface.

The nuclei of vapour bubbles grow and form vapour bubbles.

The growth period is advantageously such that the size of the bubbles prevents coalescence between the bubbles.

When the vapour bubbles have grown sufficiently, electrodes 8 are activated, and the surface above electrodes 8 changes to a hydrophilic state, which favours detachment of the vapour bubbles.

Consequently all the vapour bubbles become detached.

The electrodes then change once again to a deactivated state, and the surface covering them once again becomes a place where nucleations occur.

This control sequence continues for as long as heat dissipation is required.

The activations can be undertaken at a frequency of between 10 Hz and 100Hz.

According to the second example embodiment, the two groups of electrodes are activated alternatively, and nucleation of bubbles occurs only on a portion of the surface.

The electrodes of both groups can be positioned such that an unactivated electrode is surrounded by activated electrodes, thus preventing the appearance of a vapour layer.

The heat exchange surface is therefore the location where organised appearances occur of localised vapour bubbles which are advantageously separated from one another, thus limiting the risks of coalescence and appearance of a vapour layer.

In FIG. 13 a particularly advantageous variant embodiment of a heat exchange device D1′, according to the first embodiment, can be seen, which differs from the device of FIG. 1A in that the zones between the zones above the electrodes are hydrophilic.

The surface comprises zones Z1 naturally having hydrophobic properties located above the electrodes, and zones Z2 naturally having hydrophilic properties between hydrophobic zones Z1.

In the represented example the hydrophilic zones Z2 form a grid the squares of which are hydrophilic. During nucleation the bubbles are thus contained within the hydrophobic zones, preventing formation of a generalised vapour layer. Subsequently, when the electrodes are activated, zones Z1 become hydrophilic and, with zones Z2, tend to release the bubbles.

In this variant all electrodes 8 can be activated simultaneously, since the zones above two adjacent electrodes are separated by a hydrophilic zone, thus preventing the coalescence of two adjacent bubbles.

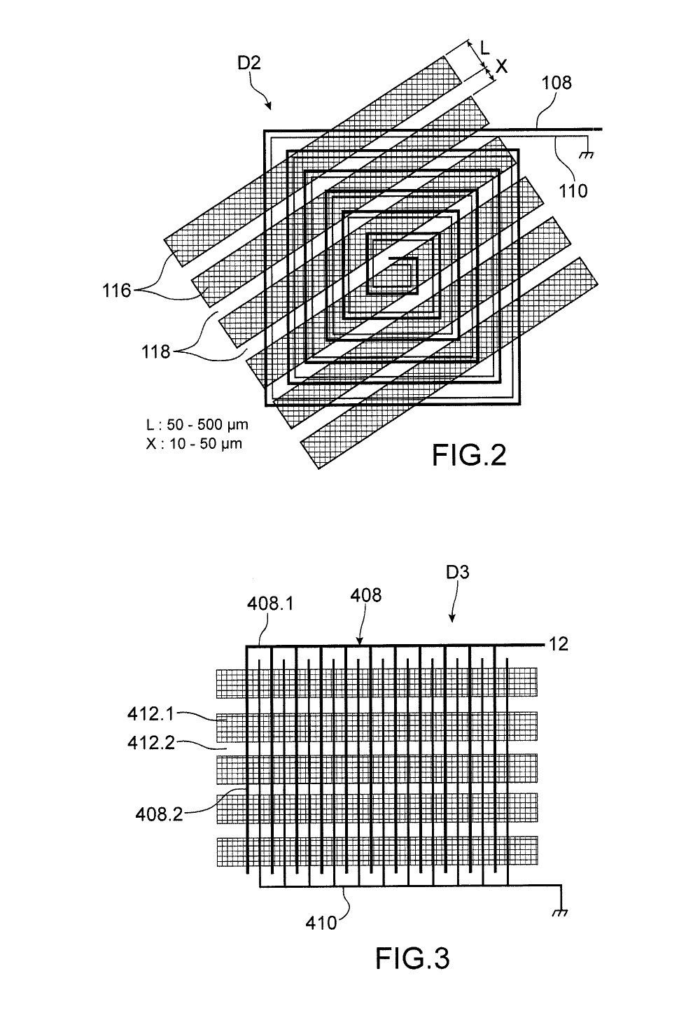

In FIG. 2 another particularly advantageous variant embodiment of a heat exchange device D2 can be seen.

In this example embodiment, device D2 comprises an electrode 108 in the form of a track connected to a voltage source 12 and a counter electrode 110 connected to earth, where the electrode and the counter electrode are parallel and run under the entire surface.

In the represented example electrode 108 and counter electrode 110 are configured in the form of a square spiral.

It is clearly understood that a circular spiral or any other shape may be used.

In addition, the bubble nucleation zones are discretised on the track in order to prevent risks of appearance of vapour lines. To accomplish this a partially hydrophilic surface is produced.

In the represented example the surface comprises hydrophilic strips 116 alternating with hydrophobic strips 118, which are at an angle relative to the track.

In the represented example the strips intersect the electrode track at 45° . The surface thus comprises, above electrode 108, hydrophobic zones alternating with hydrophilic zones.

Bubbles thus tend to appear in the hydrophobic zones, which are surrounded by hydrophilic zones. The risks of appearance of a vapour line along the electrode are prevented.

The dimensions of the tracks and their spacing are chosen as a function of the size of the bubbles.

For example, the width of the track is greater than or equal to the critical size of a nucleus of a vapour bubble, i.e. between 10 and 100 μm.

The spacing of the tracks is between 0.1 and 2 mm.

Vapour bubbles are therefore distributed along the track and take the form of a spiral in discrete fashion.

Since the track extends along the entire surface of the device, boiling spread across the entire surface is therefore obtained.

Width L of the hydrophilic strips is advantageously between 50 μm and 500 μm, and width X of the hydrophobic strips is between 10 μm and 50 μm.

The strips are obtained, for example, by means of a hydrophobic treatment, and then by forming the hydrophilic strips by oxidation by means of a laser or exposure to air under UV light.

The square or rectangular spiral shape enables the base of a container with a square or rectangular base, respectively, to be covered uniformly.

Producing tracks in a zigzag shape could also be envisaged.

In FIG. 3 a variant D3 of the device of FIG. 2 can be seen.

Device D3 comprises an electrode 408 taking the form of a comb fitted with a base 408.1 and fingers 408.2 extending transversely relative to base 408.1.

Electrode 408 is connected to a voltage source 12 in the area of its base 408.1.

Device D3 also comprises a comb-shaped counter electrode 410, the two combs being interdigitated. Thus, fingers 408.2 of electrode 408 alternate with the fingers of counter electrode 410.

In addition, the dielectric layer covering the electrodes is covered with a thin layer of alternating strips 412.1, 412.2 where those referenced 412.1 have satisfactory wettability, and the others, referenced 412.2, low wettability, and where strips 412.1, 412.2 are orthogonal to the fingers of the combs.

Consequently, each surface above each electrode in line has activatable zones with alternating non-activatable zones.

Operation of this device is similar to that of FIG. 2. A generation of nuclei of bubbles appears along fingers 408.2 at the intersections between strips 412.2 and fingers 408.2.

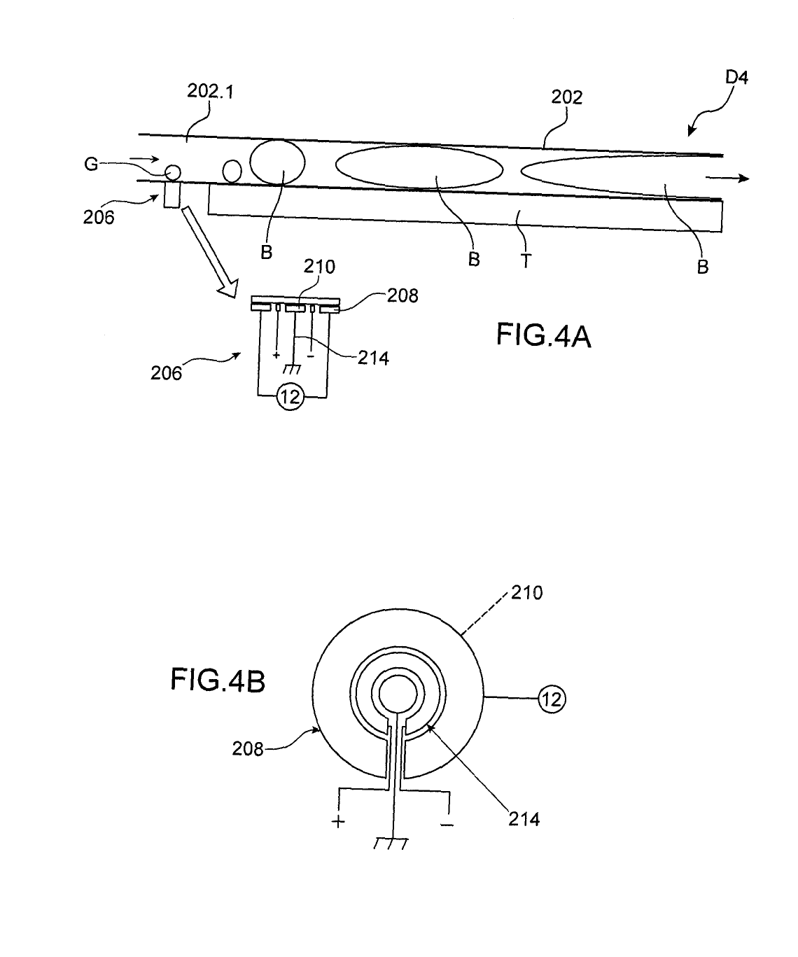

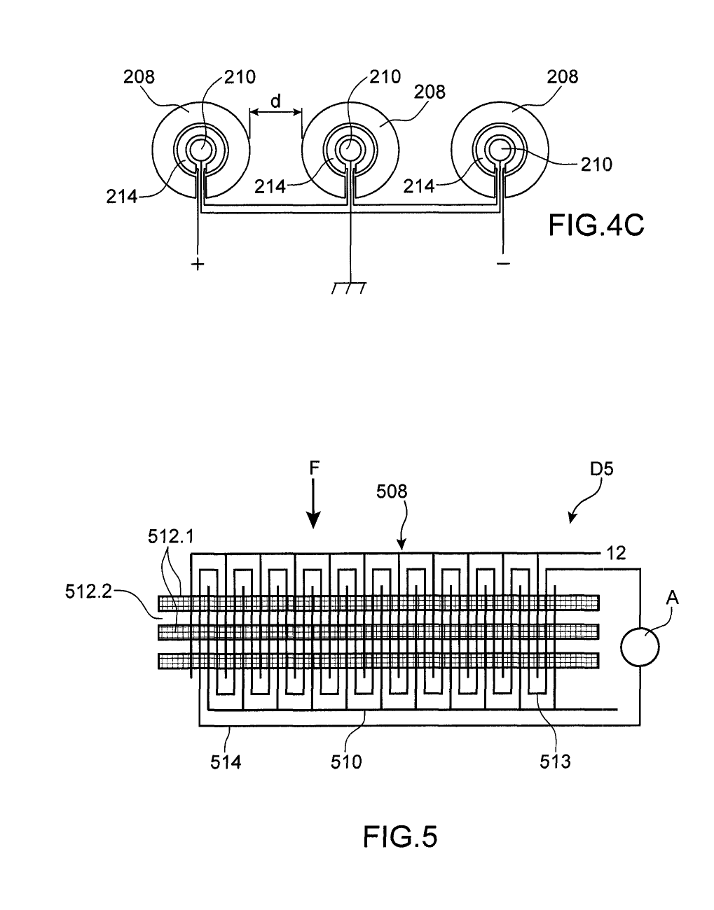

FIG. 4A shows another embodiment of a heat exchange device D4 according to the present invention.

This embodiment uses convective and confined boiling.

Heat exchange device D4 comprises a closed duct 202 of hydraulic diameter less than the capillary length of fluid 4 used to extract the calories.

This duct 202 can be in contact on one side with the element to be cooled T, or be embedded in it.

The device also comprises means (not represented) to cause the fluid to flow in channel 202.

Channel 202 comprises an end portion 202.1 upstream from the element to be cooled. The channel forms a closed circuit with the means of circulation, for example a hydraulic pump; fluid 4 beyond the portion downstream from the element is returned to the upstream end portion.

According to the present invention, the heat exchange device comprises an electro-wetting system 206 positioned in the area of the upstream end portion under the surface of the channel, and heating means 214.

The internal surface of the upstream end portion, at least in the area of electro-wetting system 206, has hydrophobic properties.

The internal surface of the portion of the duct in contact with the element to be cooled T advantageously has a hydrophilic surface to limit the appearance of nuclei of vapour bubbles outside upstream end portion 202.1.

In FIG. 4B a schematic representation can be seen of an example of an electro-wetting system 206 and of heating means 214.

The electro-wetting system comprises an annular electrode 208 connected to a voltage source 12 and a counter electrode 210 in the centre of the electrode connected to earth.

Heating means 214 are advantageously positioned between counter electrode 210 and electrode 208, in order to localise as far as possible the area of generation of nuclei of vapour bubbles.

For example, the heating means are formed by a ring-shaped electrical resistor connected to an electrical current source.

The heating means are, for example, electrical, electrodynamic, ultrasonic, piezoelectric or laser-based.

The bubbles can also be formed by using a vapour chamber.

In FIG. 4C an electro-wetting system 206 can be seen, with a view from above, comprising several electrode 208—counter electrode 210 pairs, each pair being associated with heating means 214.

This electro-wetting system 206 with several electrode/counter electrode pairs enables the entire width of the channel to be covered for one line, as can be seen in FIG. 4C, in which three assemblies are juxtaposed.

It is not necessary to have phase-shifting in the activation of electrodes 208; bubbles can be produced simultaneously which will be removed by the fluid flow.

The three electrodes 208 can be connected in parallel, and the three heating means can be connected in series.

It is clearly understood that device D4 can comprise several channels, of diameter for example less than 3 mm and of variable length, for example several cm, depending on the element to be cooled.

We shall now explain the operation of device D4.

The aim is to extract the heat from the element to be cooled. The fluid flows in channel 202.

Heating means 214 are activated; they emit heat in the upstream end portion, tending to cause the temperature of the fluid to rise in this zone.

This heat source provides sufficient energy to create a critical nucleus G of a vapour bubble under hydrophobic wall conditions.

This energy is, however, insufficient to create the same nucleus under hydrophilic wall conditions.

The heat flow in question is typically of the order of 1-50 kW/m².

There is therefore no requirement for the power of the heat source to be substantial, and it is in any event very much lower than that of the heat source formed by the element to be cooled.

The nuclei of vapour bubbles then grow and form vapour bubbles B.

Electrode 208 is then activated, causing a modification of the contact angle of the liquid surrounding the vapour bubble; the zone then becomes hydrophilic, favouring the detachment of the bubble.

Bubble B will then pass into the portion of the channel in contact with the element to be cooled, and will grow as it moves, causing vaporisation of the liquid around it, and extracting calories.

The electrode is thus switched at a frequency of the order of 10-100 Hz, which is equal to the frequency of nucleation and growth of a vapour bubble.

As an example, ring-shaped electrode 208 can have an external diameter of between 0.1 mm and 2 mm.

The counter electrode is circular, of diameter of between 1 μm and 10 μm. The distance between the electrode and the counter electrode is between 10 μm and 50 μm.

If the electro-wetting device has several electrode and counter electrode pairs these are, for example, separated by a distance of between 0.1 mm and 1 mm.

This embodiment enables the frequency of appearance of the bubbles, and their size, to be controlled.

It is thus possible to prevent the bubbles being too close to one another, coalescing, and then forming vapour locks.

In FIG. 5 another example embodiment of a device D5 according to the second embodiment can be seen, in a convective and confined boiling mode.

The direction of flow of the fluid is symbolised by arrow F.

Heat exchange device D5 comprises a comb-shaped electrode 508 connected to a voltage source 12, and a counter electrode 510, which is also comb-shaped, connected to earth.

Electrode 508 and counter electrode 510 are interdigitated.

The comb fingers are aligned roughly in the direction of flow of fluid F.

In addition, device D5 comprises heating means 514 winding between the finger of electrode 508 and the fingers of counter electrode 510.

In the represented example heating means 514 are formed by an electrical resistor connected to an electric current generator designated A.

In addition, the dielectric layer covering the electrodes is covered with a thin layer of alternating strips 512.1, 512.2 where those referenced 512.1 have satisfactory wettability, and the others, referenced 512.2, low wettability, and where strips 512.1, 512.2 are orthogonal to the fingers of electrode 508.

Consequently, each surface above each finger has activatable zones with alternating non-activatable zones.

The nuclei of vapour bubbles are generated along the length of the fingers at the intersections with the hydrophobic zones.

The bubbles are generated along lines perpendicular to the axis of the channel. These bubbles are carried away by the flow of the fluid.

The presence of alternating hydrophilic and hydrophobic zones enables the formation of a vapour strip to be prevented.

The present invention enables the heat exchange coefficient to be increased by delaying the formation of a vapour phase in the area of the wall, whether this is a device operating under pool boiling conditions or under convective and confined boiling conditions.

We shall now describe a method of production of such heat exchange devices.

A substrate 300 is used, made for example of a metal such as, for example, aluminium or copper, or of a metal alloy, or silicon dioxide.

The substrate is advantageously made from steel.

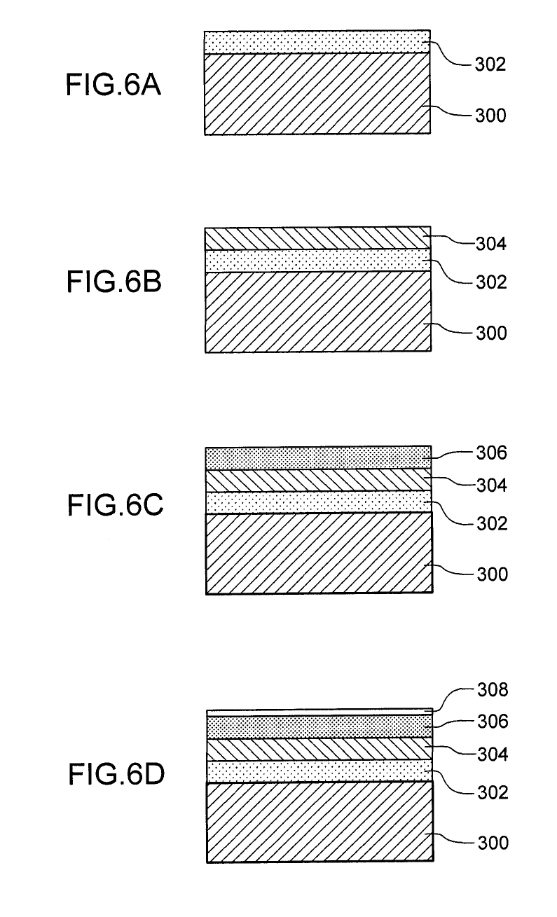

During a first step represented in FIG. 6A an electrically insulating layer 302 is deposited on the substrate; the purpose of this layer is to provide an electrical insulation between the substrate and the metal layer used for the production of the electrodes.

For example, the electrical insulating layer consists of SiC, SiN, SiO₂ or a combination of these materials.

Advantageously, layer 302 is made from SiC/SiO₂, providing satisfactory adhesion to the substrate, firstly, and to the conducting layer which will form the electrodes, secondly.

The thickness of layer 302 is chosen such that it is sufficiently low that it does not substantially affect the heat exchange between the element to be cooled and the fluid.

For example, the thickness of SiC/SiO₂ is of the order of 100 nm to 1000 nm for an apparent dielectric constant ε of the order of 2-8.

This layer can be deposited by a conventional vacuum deposition method of the PVD type (physical deposition in the vapour phase) or CVD type (chemical deposition in the vapour phase).

During a following step represented in FIG. 6B, an electrically conducting layer 304 is deposited on the electrically insulating layer 302 in the form of a thin film. Conducting layer 304 is made, for example, of copper, gold, titanium, molybdenum or another conducting material or alloy.

It is between 100 nm and 1000 nm thick, for example.

This layer can be deposited by a conventional vacuum deposition method of the PVD type.

In a following step (not represented) the electrodes are structured. This structuring can be accomplished, for example, by means of a physical mask deposited on layer 304.

The visible portion of layer 304 is then etched and the mask removed.

It is also possible to accomplish this structuring by a lift-off method, i.e. the mask made from photosensitive resin is deposited before depositing conducting layer 304, where the mask is a negative of the structure desired for the electrodes.

Conducting layer 304 is then deposited on the mask.

The mask is then eliminated, for example by means of a solvent, removing the zones of layer 304 deposited on the mask.

During a following step represented in FIG. 6C, a second electrically insulating layer 306 is deposited on the electrodes.

It is similar to the first layer 302.

It can be made from the same material or a different material.

It is, for example, between 100 nm and 1000 nm thick for an apparent dielectric constant ε of the order of 2-8.

In a following step represented in FIG. 6D, a hydrophobic layer 308 is deposited which will be in contact with the fluid. This layer is made, for example, of SiOC.

It is between 10 nm and 100 nm thick, for example.

It is deposited by a conventional vacuum deposition method of the PECVD type.

The surface energy of this layer, and more specifically its polar component, is modified under the effect of an electric field imposed by the electrodes formed in conducting layer 304, which enables its water-wetting property to be switched from the hydrophobic domain to the hydrophilic domain.

Layer 306 as described above enables, with a low voltage in metal layer 304 of below 40 V, an electric field to be generated at the surface sufficient to modify the surface energy of hydrophobic layer 308.

After the deposition of the hydrophobic layer, the surface of the hydrophobic layer can be modified locally to make it hydrophilic, for example in order to produce hydrophilic lines as described in the second example of the first embodiment.

To this end, a localised oxidation of the hydrophobic layer is accomplished, for example by using laser or UV inscription in an atmosphere containing oxygen, locally making the hydrophobic layer hydrophilic.

These oxidised zones cannot change their wettability and form barriers to the generation of nuclei of vapour bubbles and to the propagation of vapour lines.

Advantageously, it is possible to accomplish a structuring at the surface of the second insulating layer 306 prior to the deposition of hydrophobic layer 308 in order to accentuate the hydrophilic and hydrophobic properties, to attain super-hydrophilicity and super-hydrophobicity properties.

The effect of this structuring is to increase the electro-wetting dynamics.

The structure can be produced, for example, by lithography by silicon dioxide nano-beads of diameter of between 0.5 μm and 5 μm and etching of second insulating layer 306 through this mask of beads by a fluorinated plasma in order to obtain as aspect ratio of at least 2:1 (aspect ratio is the ratio of depth over width).

The carpet of beads is deposited in a single layer, for example using a Langmuir-Blodgett method.

The plasma etching causes a gradual reduction of the bead size simultaneously with the vertical etching of the underlying layer.

This effect can cause a desirable etching gradient, since it reduces the upper surface fraction, which favours the “bed of nails” effect of the super-hydrophobicity or super-hydrophilicity.

The beads are then removed by ultrasound.

The present invention applies principally to the production of diphasic heat exchangers, diphasic thermosiphons and heat pipes.

1-35. (canceled)

36. A method to implement heat exchanges by boiling a polar liquid on a surface including at least one low-wetting zone, comprising:
a) generating appearance of nuclei of vapor bubbles on said low-wetting zone, and causing said nuclei to grow; and
b) making said surface wetting by at least one electro-wetting system comprising at least one electrode associated with a counter electrode to favor detachment of said gas bubbles formed in this manner.

37. A method to implement heat exchanges by boiling according to claim 36, in which the surface is entirely low-wetting, and multiple electro-wetting systems are distributed under this surface; in b) the electro-wetting systems are all activated simultaneously to favor detachment of said gas bubbles formed.

38. A method to implement heat exchanges by boiling according to claim 36, wherein the surface comprises a number m of electro-wetting systems, distributed under the surface and configured to be activated separately, wherein m is equal to n+p, wherein m, n and p are natural integers, wherein a) and b) are applied periodically to the n and to the p electro-wetting systems, wherein a) is applied to n systems and b) to p systems simultaneously, and wherein a) is applied simultaneously to the p systems and b) to the n systems simultaneously.

39. A method to implement heat exchanges according to claim 38, in which a period of activation of the electrodes is roughly equal to the sum of a period of generation of the nuclei of vapor bubbles and of a growth period of the vapor bubbles, or is between 10 Hz and 100 Hz.

40. A method to implement heat exchanges by boiling according to claim 36, in which the system comprises an electrode in a form of a track running under the surface, wherein said surface includes, above the electrode, alternating low-wetting and wetting zones, and wherein a) and b) apply to the single electrode.

41. A method to implement heat exchanges by boiling according to claim 36, wherein said boiling is convective and confined, and the surface then forms a portion of a duct in which the polar liquid flows, wherein said surface is located upstream from the zone wherein the heat exchange takes place; the surface comprises heating means;
during a), the polar liquid undergoes a heat transfer on the surface.

42. A device for heat exchange by boiling comprising:
a surface in contact with a polar liquid and configured to extract heat from an element,
wherein said surface comprises at least one system configured to modify locally wettability of the surface in contact with the polar liquid by electro-wetting,
wherein said system comprises at least one electrode associated with a counter electrode and a controller to activate an electrode by application of a potential to said electrode,
wherein a wall of the surface has, at least partially, if no potential is applied to said electrode, low wettability properties, and
wherein the system is insulated from the liquid by a dielectric layer, such that if there is no potential nuclei of vapor bubbles and growth of said nuclei appear and, when a potential is applied, said gas bubbles formed in this manner become detached.

43. A heat exchange device according to claim 42, in which the polar liquid flows,
wherein said electro-wetting system is located in a portion of the wall upstream from a portion in contact with the element to be cooled, and
wherein said device further comprises a device to cause the liquid to flow in the duct, and a heater located in the area of the electro-wetting system.

44. A heat exchange device according to the claim 43, in which the electro-wetting system comprises at least one electrode associated with a counter electrode distributed transversely relative to the direction of flow of the liquid.

45. A heat exchange device according to claim 44, in which at least one electrode has a shape of a ring, and the counter electrode is positioned in the center of said ring.

46. A heat exchange device according to claim 45, in which the external diameter of the electrode is between 0.1 mm and 1 mm, and the diameter of the counter electrode is between 1 μm and 10 μm, wherein the distance between the electrode and the counter electrode is between 1 μm and 50 μm.

47. A heat exchange device according to claim 45, in which the distance between two adjacent electrodes is between 0.1 mm and 1 mm.

48. A heat exchange device according to one of claim 43, in which the heater is formed by a ring-shaped electrical resistor surrounded by the electrode and surrounding the counter electrode.

49. A heat exchange device according to claim 43, in which said electro-wetting system comprises a comb-shaped electrode comprising a body and fingers transverse to the body, wherein said fingers are aligned roughly in the polar liquid's direction of flow, and a comb-shaped counter electrode, wherein the fingers of the counter electrode are interdigitated with those of the electrode, wherein the surface also comprises wetting zones alternating with low-wetting zones along the fingers, and wherein the heater passes between the fingers of the electrode and those of the counter electrode.

50. A heat exchange device according to claim 49, in which the wetting zones and the low-wetting zones take a form of strips roughly perpendicular to the direction of flow of the polar liquid, and extend along the full length of the comb.

51. A heat exchange device according to claim 42, in which the boiling takes place in a vessel, wherein said surface forms the base of said device, wherein the electro-wetting system comprises multiple electrodes associated with at least one counter electrode, and wherein said electrodes are distributed over the entire surface of the wall.

52. A heat exchange device according to claim 51, in which the controller simultaneously activates and deactivates all the electrodes periodically.

53. A heat exchange device according to claim 51, in which the controller activates and deactivates the electrodes in groups or separately and periodically in a phase-shifted manner.

54. A heat exchange device according to claim 51, in which the electrodes are distributed as on a draughtsboard.

55. A heat exchange device according to claim 54, in which the entire surface is low-wetting.

56. A heat exchange device according to claim 54, in which the zones above the electrodes are low-wetting and the zones between the zones above the electrodes are wetting.

57. A heat exchange device according to claim 56, in which the wetting zones take a form of a grid.

58. A heat exchange device according to claim 42, in which boiling takes place in a vessel, wherein said surface forms a base of said device, wherein the electro-wetting system comprises an electrode in a form of a track running under the surface of the wall, and a counter electrode in a form of a track passes beside the electrode.

59. A heat exchange device according to claim 58, in which the surfaces above the tracks are divided into zones of low wettability by zones of satisfactory wettability.

60. A heat exchange device according to claim 58, in which the electrode and the counter electrode are configured in a form of a spiral.

61. A heat exchange device according to claim 60, in which the surface above the electrodes comprises first strips having properties of satisfactory wettability, and second strips having properties of low wettability, wherein said first and second strips alternate and intersect the various portions of the electrode.

62. A heat exchange device according to claim 58, in which the electrode and the counter electrode take a form of interdigitated combs, wherein the surface includes wetting zones and low-wetting zones above the electrode.

63. A heat exchange device according to claim 62, in which the wetting zones and low-wetting zones are formed by wetting and low-wetting strips intersecting the combs' fingers.

64. A heat exchange device according to claim 42, in which the polar liquid is water or an ethylene glycol.

65. A method for production of a thermal exchange device according to claim 42, comprising:
a) deposition of a first electrical insulating layer on a substrate;
b) deposition of an electrical conducting layer on said electrical insulating layer to form electrodes;
c) deposition of a second electrical insulating layer on the electrical conducting layer; and
d) deposition on the second electrical insulating layer of a film having low wettability properties.

66. A method of production of a heat exchange device according to claim 65, further comprising e) production in the film of zones having satisfactory wettability properties.

67. A method of production of a heat exchange device according to claim 65, in which e) is obtained by oxidization of the film having low wettability properties by a laser.

68. A method of production of a heat exchange device according to claim 65, further comprising etching of the electrical conducting layer.

69. A method of production of a heat exchange device according to claim 65, in which the substrate is made of steel, and the first electrically insulating layer is made of SiC/SiO₂.

70. A method for production of a thermal exchange device according to claim 65, in which the layer of low wettability is made of SiOC.
